(19) United States
(12) Patent Application Publication
(10) Pub. No.: US 2010/0124819 A1
(43) Pub. Date: May 20, 2010

(54) Method of manufacturing nonvolatile semiconductor memory device

(75) Inventor: Kensuke Taniguchi, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/591,365

(22) Filed: Nov. 17, 2009

(30) Foreign Application Priority Data
Nov. 18, 2008 (JP) 2008-294260

(51) Int. Cl. H01L 21/28

(52) U.S. Cl. 438/593; 257/E21.209

(57) ABSTRACT

A method of manufacturing a nonvolatile semiconductor memory device, is achieved by forming a word gate on a gate insulating film which is formed on a wafer substrate; by forming charge accumulation films to cover a surface of the wafer substrate, side surfaces of the word gate and an upper surface of the word gate; by forming a conductive film to cover the charge accumulation film; and by forming control gates by etching the conductive film. The forming the control gates is achieved by setting an etching condition in which a bias power of 100 W to 1500 W is applied to a cathode electrode as a wafer stage on which the wafer substrate is arranged; and by performing anisotropic dry etching.

### INCORPORATION BY REFERENCE

This patent application claims a priority on convention based on Japanese Patent Application No. 2008-294260. The disclosure thereof is incorporated herein by reference.

### BACKGROUND OF THE INVENTION

1. Field of the Invention

The present invention relates to a manufacturing method of a nonvolatile semiconductor memory device.

2. Description of Related Art

A semiconductor memory which can freely perform erasure, write, and read of data and in which a stored data is not erased even when a power is turned off, (hereinafter, to be referred to as a “nonvolatile semiconductor memory device”) is mounted on various electronic devices. In accompaniment with demands for downsizing and light weight of such electronic devices and also demands for achieving a higher function and a higher performance, a nonvolatile semiconductor memory device is demanded to store many data while suppressing increase in a chip area. For example, such a technique is described in Japanese Patent Application Publication (JP 2007-184323A: first conventional example). In addition, a technique which can achieve higher operation speed in such a nonvolatile semiconductor memory device is described in Japanese Patent Application Publication (JP 2002-231829A: second conventional example).

Specifically, the semiconductor device described in the first conventional example has a MONOS (Metal Oxide Nitride Oxide Semiconductor) structure or a SONOS (Silicon Oxide Nitride Oxide Semiconductor) structure, which has an ONO (Oxide Nitride Oxide) film. Thus, the semiconductor device has a Twin-MONOS structure, in which a selection gate electrode (a control gate electrode), a memory node insulating film, and a control gate electrode (a memory gate electrode) are provided, and also one control gate electrode is provided on each side surface of the selection gate electrode.

In a process of manufacturing the semiconductor device, after the selection gate electrode is formed though a control gate insulating film, the memory node insulating film is formed on a surface of a semiconductor substrate. Then, the control gate electrode is formed on a surface of the memory node insulating film. In a process of forming the control gate electrode, a control gate electrode layer is formed on the surface of the memory node insulating film, and an auxiliary film whose etching rate is smaller than that of the control gate electrode layer, is formed on a surface of the control gate electrode layer. Then, anisotropic etching is performed on the control gate electrode layer and the auxiliary film. In the first conventional example, the control gate electrode with high minimum height in a width direction is formed.

In the second conventional example, a nonvolatile semiconductor memory device can perform a high-speed operation by siliciding the surface of a silicon electrode (region). FIG. 1 is a sectional view showing a structure of the nonvolatile semiconductor memory device in the second conventional example. The nonvolatile semiconductor memory device is provided with a selection gate electrode G1 formed on a channel region 130 through a first gate insulating film 102. Moreover, control gate electrodes G3a and G3b are formed on side surfaces of the selection gate electrode G1 through gate separation insulating films 121 in a side wall shape. The control gate electrodes G3a and G3b and the selection gate electrode G1 have a predetermined height difference. A silicide layer 109 is formed on a surface of each of the electrodes G1, G3a, and G3b. Since the control gate electrodes G3a and G3b and the selection gate electrode G1 have the height difference, it is possible to insulate the silicide layers 109 formed on their surfaces from one another while arranging the gate electrodes closely to one another without locating them away from one another.

In manufacturing a conventional nonvolatile semiconductor memory device having the Twin-MONOS structure, these two control gate electrodes are simultaneously formed by etching using a self align technique. At this time, the control gate electrodes G3a and G3b and the selection gate electrode G1 are formed so that the predetermined height difference is provided. More specifically, heights of the control gate electrodes G3a and G3b are made lower than that of the selection gate electrode G1, thereby avoiding generation of a short-circuit between the selection gate electrode G1 and the control gate electrodes G3a and G3b.

In this nonvolatile semiconductor memory device, in order to give a necessary device characteristic the control gate electrodes requires to be formed to have limited sizes. For example, if the control gate electrodes G3a and G3b are excessively reduced in size in order to avoid generation of a short-circuit, a wiring resistance increases, which may cause a problem in an operation of the nonvolatile semiconductor memory device. In order to prevent the increase in the wiring resistance while avoiding generation of the short-circuit between the selection gate electrode G1 and the control gate electrode G3a (or control gate electrode G3b), there has been a demand for a very high precise in the etching process.

The inventor of the present invention has recognized as follows. In a conventional nonvolatile semiconductor memory device having the Twin-MONOS structure, even when etching is executed in a high precise, there is a case that two control gate electrodes formed in a lateral direction of a selection gate electrode do not have a symmetrical side wall shape. Moreover, in some cases, shape variation has arisen between an element formed on a chip in an outer circumference portion of a wafer and an element formed on a chip around a center of the wafer.

The asymmetry and shape variation are not considered as problems in a conventional nonvolatile semiconductor memory device. However, further fine processing of a semiconductor manufacturing process brings the asymmetry and shape variation into significant problems. They are new problems found in association with the fine processing, and are not found in the conventional nonvolatile semiconductor memory device having the Twin-MONOS structure.

### SUMMARY OF THE INVENTION

In an aspect of the present invention, a method of manufacturing a nonvolatile semiconductor memory device, is achieved by forming a word gate on a gate insulating film which is formed on a wafer substrate; by forming charge accumulation films to cover a surface of the wafer substrate, side surfaces of the word gate and an upper surface of the word gate; by forming a conductive film to cover the charge accumulation film; and by forming control gates by etching the conductive film. The forming the control gates is achieved by setting an etching condition in which a bias power of 100 W to 1500 W is applied to a cathode electrode as a wafer stage on which the wafer substrate is arranged; and by performing anisotropic dry etching.

According to the present invention, two control gate electrodes formed in a lateral direction of a word gate electrode can have a symmetrical structure at any location of a wafer. Specifically, shape variation can be suppressed between an element formed on a chip at an outer circumferential portion of a wafer and an element formed on a chip around a center of this wafer. Moreover, side surfaces of the control gate in a side wall shape can be formed to be vertical, which makes it possible to control the shape of the control gates with a high accuracy.

### BRIEF DESCRIPTION OF THE DRAWINGS

The above and other objects, advantages and features of the present invention will be more apparent from the following description of certain embodiments taken in conjunction with the accompanying drawings, in which:

FIG. 1 is a sectional view showing a configuration of a conventional nonvolatile semiconductor memory device;

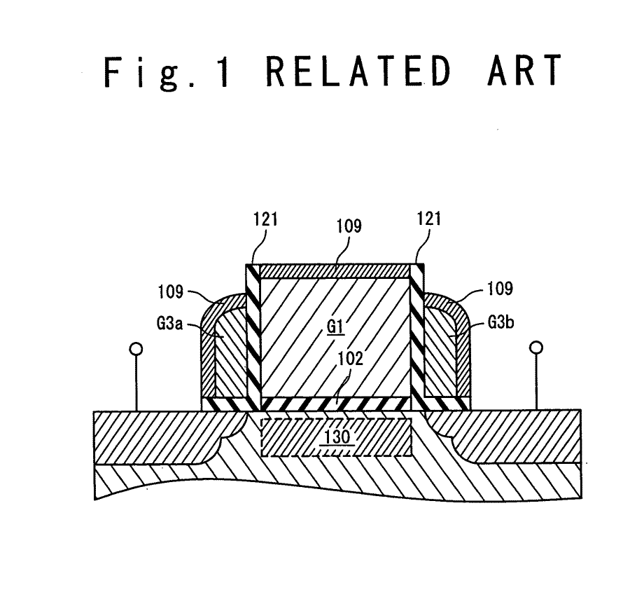

FIG. 2 is a sectional view illustrating a configuration of a nonvolatile semiconductor memory device according to an embodiment of the present invention;

FIG. 3 is a diagram illustrating a configuration of an etching unit;

FIG. 4 is a sectional view illustrating a first process of manufacturing the nonvolatile semiconductor memory device in the embodiment;

FIG. 5 is a sectional view illustrating a second process of manufacturing the nonvolatile semiconductor memory device in the embodiment;

FIG. 6 is a sectional view illustrating a third process of manufacturing the nonvolatile semiconductor memory device in the embodiment;

FIG. 7 is a sectional view illustrating a fourth process of manufacturing the nonvolatile semiconductor memory device in the embodiment;

FIG. 8 is a sectional view illustrating a fifth process of manufacturing the nonvolatile semiconductor memory device in the embodiment;

FIG. 9 is a diagram illustrating how control gates are typically processed;

FIG. 10 is a graph showing relationship between a condition that a cathode side is provided with high power and bilateral asymmetry of the control gates;

FIG. 11 is a sectional view illustrating a sixth process of manufacturing the nonvolatile semiconductor memory device in the embodiment;

FIG. 12 is a graph showing relationship between etching time and shapes of the control gates;

FIG. 13 is a graph showing relationship between a film thickness of a second conductive film and the shapes of the control gates; and

FIGS. 14A and 14B are views illustrating a shape of a conventional nonvolatile semiconductor memory device and a shape of the nonvolatile semiconductor memory device of the present embodiment.

### DESCRIPTION OF THE EMBODIMENTS

Hereinafter, a nonvolatile semiconductor memory device of the present invention will be described with reference to the attached drawings. It should be noted that in the drawings, same elements are basically assigned with same numerals, and same description thereof will be omitted.

A nonvolatile semiconductor memory device having an ONO (Oxide Nitride Oxide) film as a charge accumulation film is exemplified in the following embodiments. For example, the nonvolatile semiconductor memory device having an ONO film of a MONOS (Metal Oxide Nitride Oxide Semiconductor) structure or a SONOS (Silicon Oxide Nitride Oxide Semiconductor) structure is shown. In this nonvolatile semiconductor memory device, write is performed by injecting electrons into the ONO film. Moreover, data is erased by injecting holes into the ONO film so as to re-combine with the stored electrons.

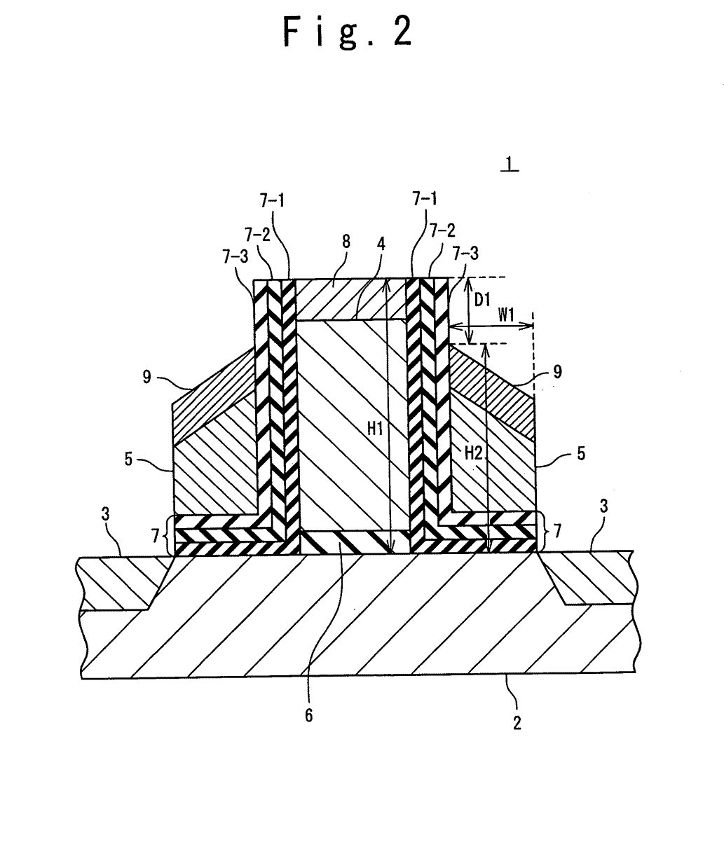

FIG. 2 is a sectional view illustrating a structure of the nonvolatile semiconductor memory device 1 of the present embodiment. The nonvolatile semiconductor memory device 1 includes a substrate 2, source/drain diffusion layers 3, a Word gate 4, and control gates 5. A word gate silicide layer 8 is provided on the word gate 4. Control gate silicide layers 9 are provided on the control gates 5, respectively. A gate insulating film 6 is provided between the substrate 2 and the word gate 4. Charge accumulation layers 7 (ONO film) are provided between the substrate 2 and the control gates 5. The charge accumulation layer 7 includes a region extending in a height direction along side surfaces of the word gate 4. The region of the charge accumulation layer 7 electrically insulates the word gate 4 and the control gates 5 from each other. The charge accumulation layer 7 includes a first oxide film 7-1, a nitride film 7-2, and a second oxide film 7-3. In the nonvolatile semiconductor memory device 1, write is performed by injecting electrons into the nitride film 7-2, and erasure is performed by injecting holes into the nitride film 7-2 and then recoupling them with the accumulated electrons.

As shown in FIG. 2, a height from an interface between the substrate 2 and the gate insulating film 6 to a top surface of the word gate silicide layer 8 is a first height H1. Furthermore, a height from an interface between the substrate 2 and the charge accumulation layer 7 to an uppermost part of the control gate silicide layer 9 is a second height H2. A difference between the upper surface of the word gate silicide layer 8 and the uppermost part of the control gate silicide layer 9 in the nonvolatile semiconductor memory device 1 of the present embodiment is a height difference D1. A width of the control gate 5 is a width W1.

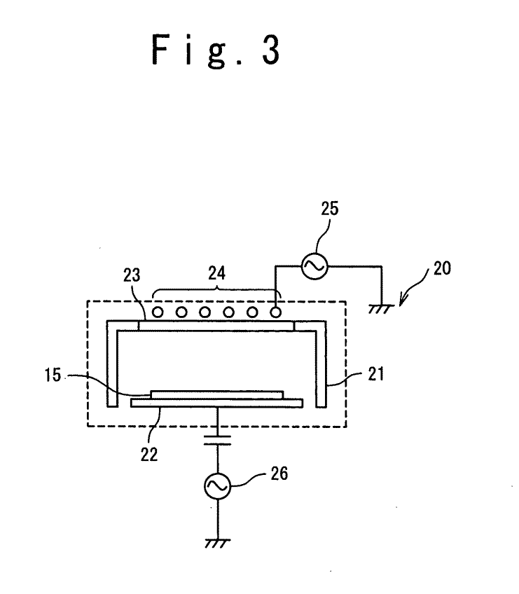

FIG. 3 is a drawing illustrating a structure of an etching apparatus 20 used upon manufacturing the nonvolatile semiconductor memory device 1 of the present embodiment. In the following embodiment, an example is exemplified which the etching apparatus 20 is an ICP (Inductively Coupled Plasma) type etching apparatus compatible with a wafer substrate with the diameter of 300 mm. The etching apparatus 20 is provided with a chamber 21. The chamber 21 includes a substrate installation base 22 and a dielectric window 23. A wafer substrate 15 is arranged on the substrate installation base 22. Coils 24 are provided around the dielectric window 23. The coil 24 generates plasma inside the chamber 21. The coil 24 is connected to a first high-frequency power source 25. The substrate installation base 22 is connected to a second high-frequency power source 26. A gas introduction port (not shown) for introducing etching gas; and a gas exhaust port (not shown) for exhausting the etching gas to provide a predetermined pressure inside the chamber 21 are provided in the chamber 21.

The etching apparatus 20 illustrated in the present embodiment meets an etching condition described below:
Pressure: 2 to 100 mTorr,
Top Power: 200 to 1000 W,
Bias Power: 100 to 1500 W (250 to 1000V),
Bias frequency: 13.56 MHz, and
Gas: Cl₂ or HBr (One or more of He, N₂, O₂, and Ar may be mixed).

For example, in the following description, when a mixing gas of HBr, O₂, and He is used as the etching gas, it is. preferable that no inconsistency arises in a range:
HBr: 20 to 500 sccm,
O₂: 0 to 10 sccm, and
He: 0 to 500 sccm.
   In addition, in this case, it is more preferable that a ratio of HBr and O₂ be 10:1 or larger.

In the above etching condition, it is more preferable that the pressure be in a range of 20 to 50mTorr. Moreover, it is more preferable that the Bias Power be in a range of 150 to 500 W (300 to 600V). It should be noted that the above etching condition is a condition example of the ICP type of etching apparatus compatible with a wafer with the diameter of 300 mm. Thus, for a case of an etching apparatus compatible with a wafer substrate with a different diameter, it is preferable that the condition is changed in accordance with this apparatus.

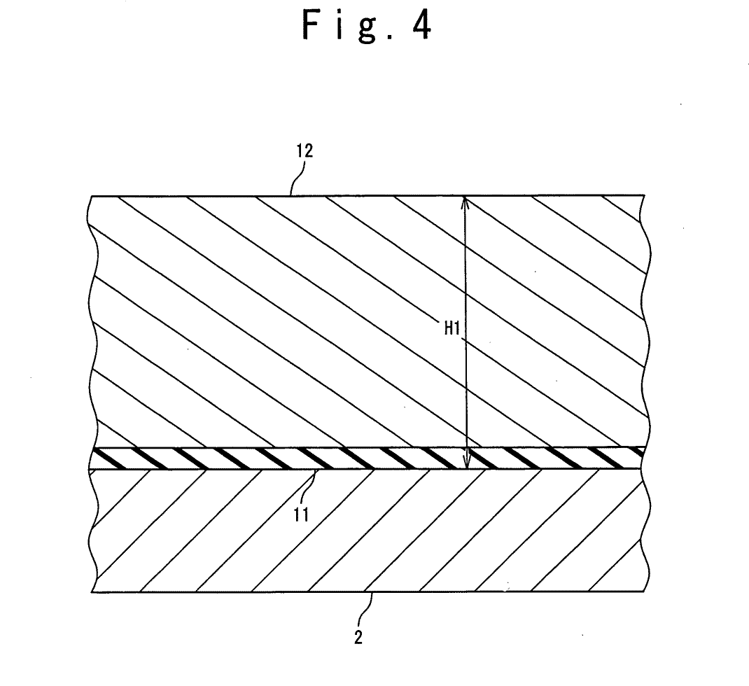

Hereinafter, a process of manufacturing the nonvolatile semiconductor memory device 1 of the present embodiment will be described. FIG. 4 is a sectional view illustrating a first process in the processes of manufacturing the nonvolatile semiconductor memory device 1. In the first process, a first insulating film 11 is formed on the substrate 2 to serve as the gate insulating film 6. Then, a first conductive film (polysilicon film) 12 is formed on the first insulating film 11, so that a height from a surface of the substrate 2 (an interface between the substrate 2 and the first insulating film 11) to the upper surface of the first conductive film 12 is the first height H1.

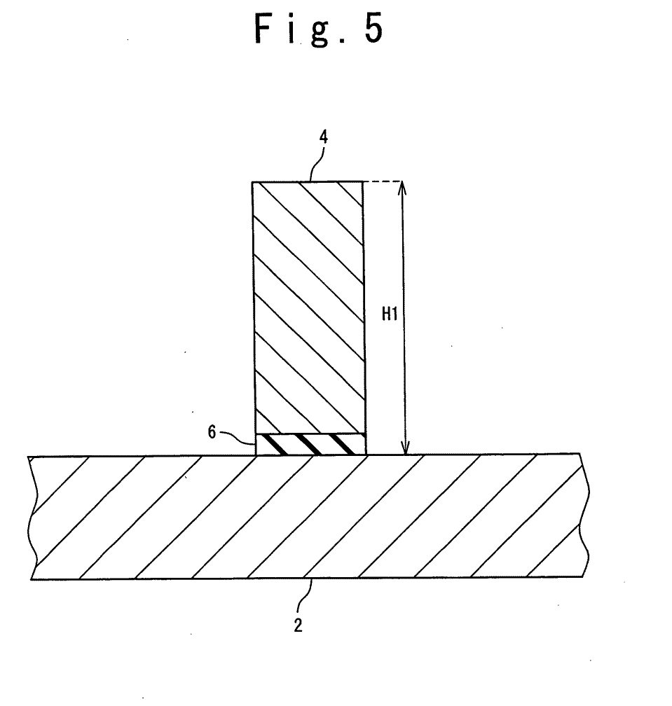

FIG. 5 is a sectional view illustrating a second process of manufacturing the nonvolatile semiconductor memory device 1. In this second process, a resist pattern (not shown) formed on the first conductive film 12 is used as a mask and the first conductive film 12 is etched to form the word gate 4. Then, the word gate 4 is used as a mask, to selectively remove the first insulating film 11 by etching in a self align to thereby form the gate insulating film 6.

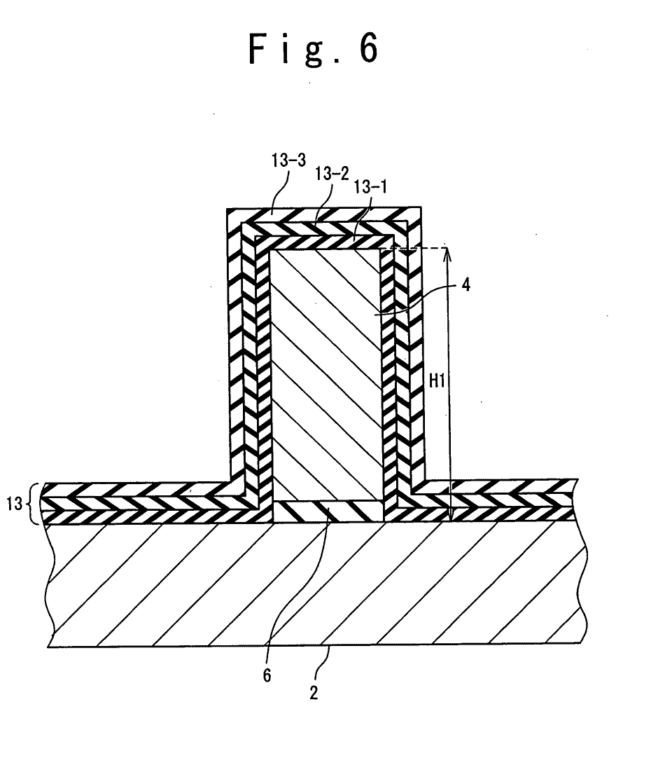

FIG. 6 is a sectional view illustrating a third process of manufacturing the nonvolatile semiconductor memory device 1. In the third process, an ONO film 13 is formed to cover the surface of the substrate 2 exposed by removing the first insulating film 11, a side surface of the gate insulating film 6, the side surface of the word gate 4, and a top surface of the word gate 4. The ONO film 13 includes a first oxide film 13-1, a nitride film 13-2, and a second oxide film 13-3. The ONO film 13 serves as the charge accumulation layer 7 in a later process. Moreover, the first oxide film 13-1, the nitride film 13-2, and the second oxide film 13-3 serve as the first oxide film 7-1, the nitride film 7-2, and the second oxide film 7-3 in a later process.

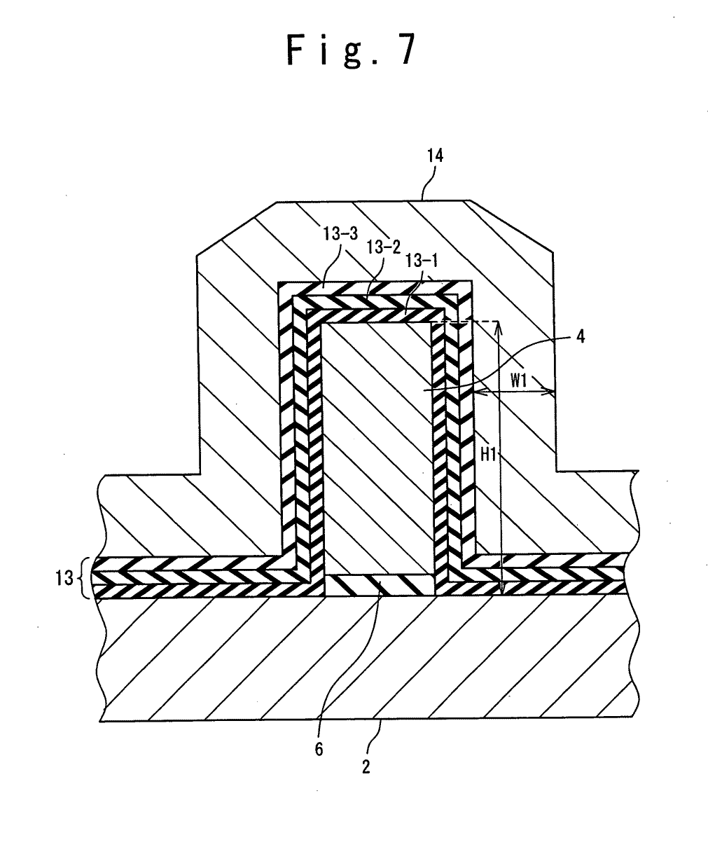

FIG. 7 is a sectional view illustrating a fourth process of manufacturing the nonvolatile semiconductor memory device 1. In the fourth process, a second conductive film (polysilicon film) 14 is formed on the ONO film 13. As shown in FIG. 7, in the fourth process, the thickness of the second conductive film 14 is equal to the width W1. In the fourth process, it is possible to change this width W1, i.e., the width W1 of the control gate 5 of the nonvolatile semiconductor memory device 1.

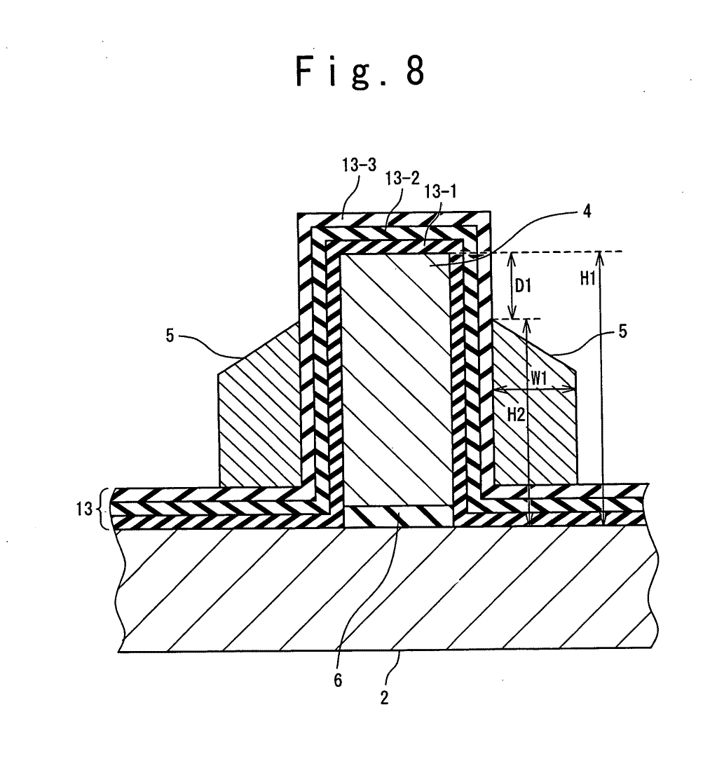

FIG. 8 is a sectional view illustrating a fifth process of manufacturing the nonvolatile semiconductor memory device 1. In the fifth process, the two control gates 5 are simultaneously formed by etching back the second conductive film 14. As shown in FIG. 8, a difference between an uppermost part of the word gate 4 and an uppermost part of each control gate 5 is equal to the height difference D1. It is preferable that the height difference D1 be approximately 70 nm.

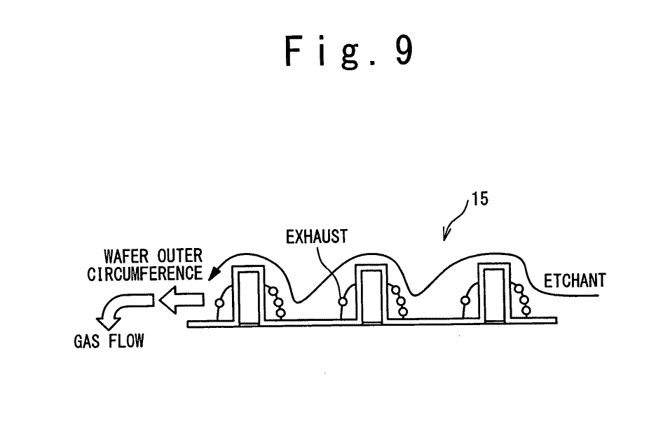

FIG. 9 is a diagram illustrating how the control gates 5 are typically processed. In formation of the control gates 5, the control gates 5 should be formed symmetrically with respect to the word gate 4. However, in some cases, the side wall shape is asymmetrical to each other in a wafer outer circumferential portion. As shown in FIG. 9, this is because a gas flow becomes increasingly faster in a portion closer to the wafer outer circumference.

In the fifth process of the present embodiment, in a process of forming the control gates 5 in a side-wall shape, an etching condition is set in which etching resultant product is likely to adhere to side surface portions of the control gates 5. More specifically, a cathode side of the etching apparatus is applied with the high bias of, for example, 150 to 250 W (300 to 500V).

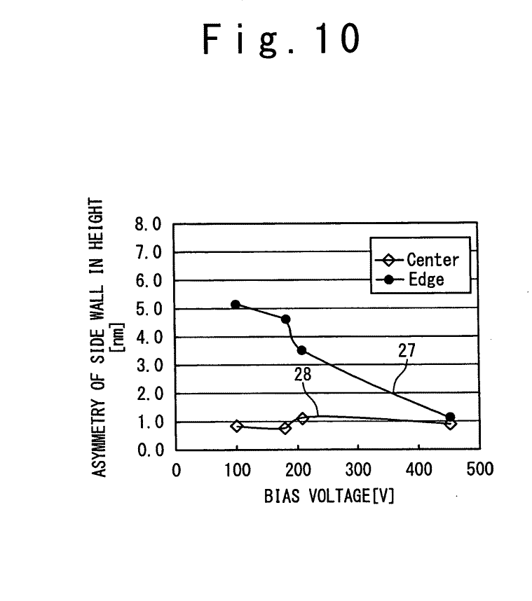

FIG. 10 is a graph showing a relationship between the etching condition in which the etching resultant product is likely to adhere to the side surfaces of the control gates 5 (a condition in which the cathode side is provided with high power) and asymmetry of the control gates 5. Providing the cathode side with high power results in a condition in which the etching is performed mainly through an ionicity effect. As shown in FIG. 10, the high ionicity can minimize influence of a gas flow field, thereby solving the problem of asymmetry.

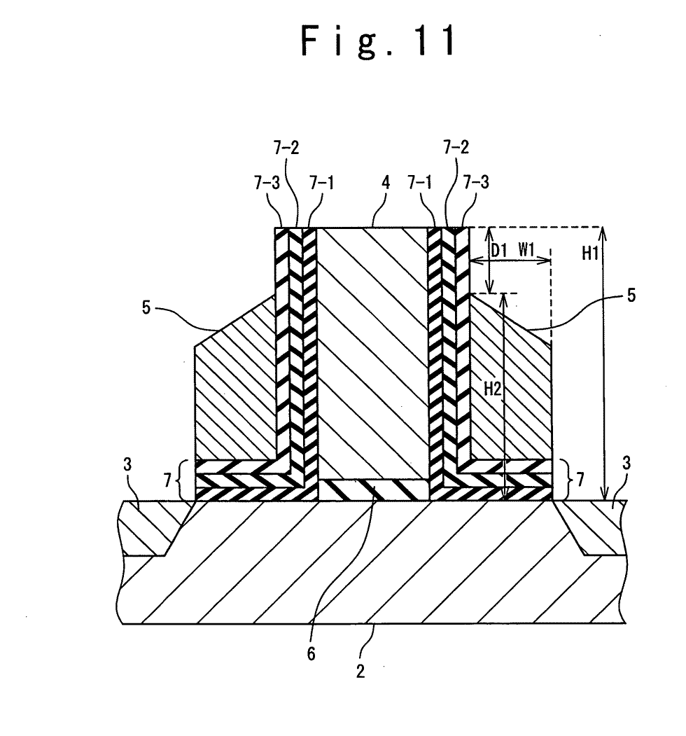

FIG. 11 is a sectional view illustrating a sixth process of manufacturing the nonvolatile semiconductor memory device 1. In this sixth process, the ONO film 13 is selectively removed to expose the top surface of the word gate 4 and the surface of the substrate 2 in a lateral direction to the control gates 5. As shown in FIG. 11, the charge accumulation layers 7 are formed by selectively removing the ONO film 13. After completing the formation of the charge accumulation layers 7, an impurity is implanted into the exposed substrate 2 to form the source/drain diffusion layers 3. Thereinafter, the control gate silicide layer 8 on the word gate 4 and the control gate silicide layers 9 on the control gates 5 are simultaneously formed to form a memory cell as shown in FIG. 2.

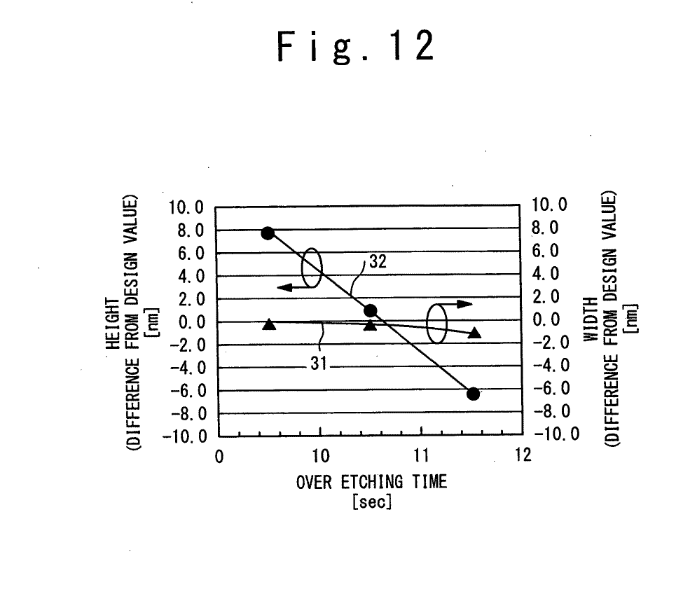

FIG. 12 is a graph showing relationship between an etching time and the shapes of the control gates 5 in the process of forming the control gates 5 of the present embodiment. A line 31 shows a change in the height of the control gate 5 over passage of etching time. A line 32 shows a change in the width of the control gate 5 over the passage of etching time. As described above, providing the etching condition in which the etching resultant product is likely to adhere to the side surfaces of the control gates 5 permits the shape of the side surface of the control gate 5 to be kept substantially vertical over the passage of time. The width of the control gate 5 in this case is equal to a film thickness when the second conductive film 14 is formed. Moreover, as shown in FIG. 12, in the fifth process, even if the etching time is extended, the width of the control gate 5 remain the same, and only the height of the control gate 5 can be controlled.

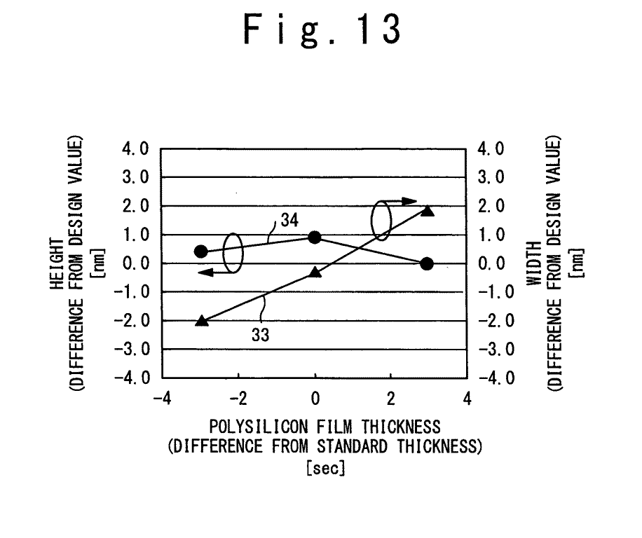

FIG. 13 is a graph showing a relationship between the film thickness when the second conductive film 14 is formed and the shape of the control gate 5 in the process of forming the control gate 5 in the present embodiment. A line 33 shows the width of the control gate 5 when the second conductive film 14 is etched to change the film thickness of the second conductive film 14. A line 34 shows the height of the control gate 5 when the second conductive film 14 is etched to change the film thickness of the second conductive film 14.

As shown in FIG. 13, the width of the control gate 5 can be freely changed by changing the film thickness when the second conductive film 14 is formed. At this point, the height of the control gate 5 is kept substantially constant without depending on the film thickness of the second conductive film 14. Therefore, the height of the control gate 5 in the nonvolatile semiconductor memory device 1 in the present embodiment can be controlled by the etching time. Then, the width of the control gate 5 can be controlled based on the film thickness when the second conductive film 14 is formed. Here, the width and the height of the control gate 5 are controlled independently from each other, which makes it possible to achieve a precise shape control.

It should be noted that in the manufacturing of the nonvolatile semiconductor memory device 1 of the embodiment, the used etching apparatus 20 is not limited to an ICP type. For example, in a case of an etching apparatus with a low-frequency bias, a same effect as that of the above embodiment can be achieved by applying the following condition:
Pressure: 2 to 50 mTorr,
Bias Power: 50 to 400 W,
Bias frequency: 400 kHz, and
Gas Cl₂ or HBr (One or more of He, N₂, O₂, and Ar may be mixed).

### COMPARATIVE EXAMPLE

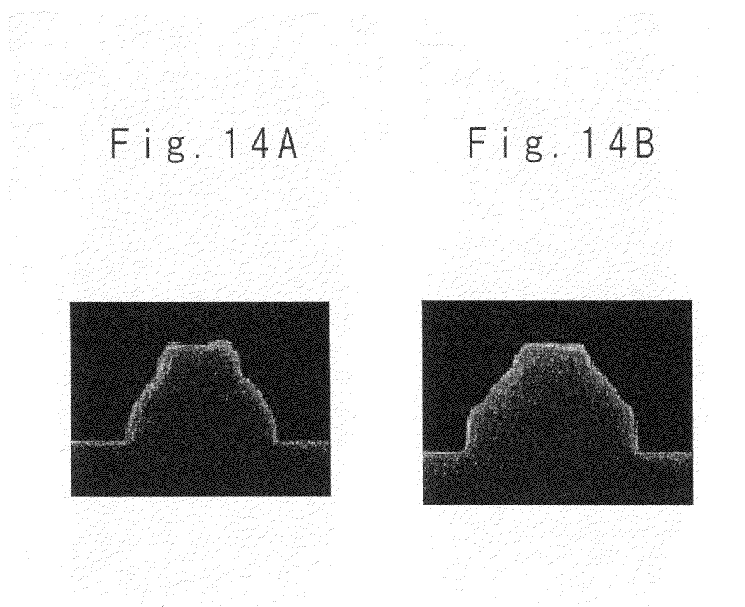

FIGS. 14A and 14B show a nonvolatile semiconductor memory device 101 manufactured by a conventional manufacturing method and the nonvolatile semiconductor memory device 1 to which the manufacturing method of the present embodiment is applied. FIG. 14A shows the processed shapes of the control gate 5 manufactured by the conventional manufacturing method. The conventional nonvolatile semiconductor memory device 101 has a control gate electrode G3a (or a control gate electrode G3b) formed to have a tight shoulder shape, as shown in FIG. 14A. On the other hand, FIG. 14B shows the shape of the control gate 5 of the nonvolatile semiconductor memory device 1 formed by the manufacturing method of the present embodiment. As shown in FIG. 14B, the control gates 5 are formed to have side wall shapes and have their vertical side surfaces.

The nonvolatile semiconductor memory device 1 shown in FIG. 14B adopts the above manufacturing method, and the high power of 450V is applied on a cathode side of an ICP apparatus upon the formation of the control gates 5. Using this etching condition solves a problem that the side wall shapes of the control gates 5 are asymmetrical to each other in the memory cell at the wafer outer circumferential portion. Moreover, the control gate 5 is processed to have the side wall shape of the film thickness of the second conductive film 14. Thus, the width of the control gate 5 can be precisely controlled by the film thickness when the second conductive film 14 is formed. Furthermore, the heights of the control gates 5 can be controlled independently from the widths of the control gates 5, thus making it possible to achieve a very precise shape control.

The embodiment of the present invention has been described above in detail. However, the present invention is not limited to the embodiment described above, and permits various modifications within a range not departing from its sprits.

What is claimed is:

1. A method of manufacturing a nonvolatile semiconductor memory device, comprising:
forming a word gate on a gate insulating film which is formed on a wafer substrate;
forming, charge accumulation films to cover a surface of said wafer substrate, side surfaces of said word gate and an upper surface of said word gate;
forming a conductive film to cover said charge accumulation film; and
forming control gates by etching said conductive film,
wherein said forming said control gates comprises
setting an etching condition in which a bias power of 100 W to 1500 W is applied to a cathode electrode as a wafer stage on which said wafer substrate is arranged; and
performing anisotropic dry etching.

2. The method according to claim 1, wherein said forming said control gates comprises:
setting the etching condition in which the bias power of 150 W to 500 W is applied to the cathode electrode on which said wafer substrate is arranged; and
performing the anisotropic dry etching.

3. The method according to claim 1, wherein said forming said control gates comprises:
performing the etching until an uppermost part of said control gate becomes lower than an upper surface of said word gate.

4. The method according to claim 1, wherein said forming said conductive film comprises:
forming said conductive film to have a target width of said control gate.

5. The method according to claim 1, further comprising:
forming a silicide layer on upper surfaces of said word gate and said control gates.
